(19) United States
(12) Patent Application Publication
(10) Pub. No.: US 2022/0082672 A1
(43) Pub. Date: Mar. 17, 2022

(54) TOF OPTICAL SENSING MODULE WITH STRAY-LIGHT GUIDE-AWAY STRUCTURE

(71) Applicant: Egis Technology Inc., Taipei City (TW)

(72) Inventors: BRUCE C.S. CHOU, Taipei City (TW); CHEN-CHIH FAN, Taipei City (TW)

(21) Appl. No.: 17/358,574

(22) Filed: Jun. 25, 2021

Related U.S. Application Data
(60) Provisional application No. 63/077,895, filed on Sep. 14, 2020.

(30) Foreign Application Priority Data
Apr. 8, 2021 (CN) 202120708972.1

(51) Int. Cl. G01S 7/486; G01S 17/10

(52) U.S. Cl. CPC G01S 7/4868; H04N 5/232; G01S 17/10

(57) ABSTRACT

A TOF optical sensing module to be disposed below a protection cover plate includes: a substrate; a cap having a cap body, and a receiving window, a transmitting window and a stray-light guide-away structure, which are connected to the cap body, wherein the cap and the substrate commonly define a chamber body; and a transceiving unit, which is disposed on the substrate, in the chamber body, outputs detection light through the transmitting window, and receives sensing light through the receiving window. The stray-light guide-away structure is disposed between an outer side between the protection cover plate and the cap body and between the transmitting window and the receiving window, and stops stray light from entering the transceiving unit through the receiving window.

### CROSS-REFERENCE TO RELATED APPLICATIONS

This application claims priorities of U.S. Provisional Patent Application Ser. No. 63/077,895, filed on Sep. 14, 2020; and China Patent Application Ser. No. 202120708972.1, filed on Apr. 8, 2021, the entire contents of which are hereby incorporated by reference.

### BACKGROUND OF THE INVENTION

### Field of the Invention

This disclosure relates to a time of flight (TOF) optical sensing module, and more particularly to a TOF optical sensing module with a stray-light guide-away structure.

### Description of the Related Art

Today's smart phones, tablet computers or other handheld devices are equipped with optical modules to achieve gesture detecting, 3D imaging, proximity detecting or camera focusing and other functions. The TOF sensor emits near infrared light toward the scene to measure the distance from the object in the scene according to the TOF or phase information of light. The advantages of the TOF sensor include the small depth information calculation loading, the strong anti-interference and the long measurement range, so it has gradually been favored.

The core components of the TOF sensor include: a light source, more particularly an infrared vertical cavity surface emitting laser (VCSEL); a photosensor, more particularly a single photon avalanche diode (SPAD); and a time-to-digital converter (TDC). The SPAD is a photoelectric detection avalanche diode having the single photon detection ability of generating a current as long as a weak optical signal is received. The VCSEL in the TOF sensor emits a pulse wave to the scene, the SPAD receives the pulse wave reflected back from the target object, the TDC records the time interval between the time of emitting and receiving the pulses, and the depth information of the to-be-measured object is calculated according to the TOF.

FIG. 1 is a schematic view showing a conventional TOF optical sensing module 300. Referring to FIG. 1, the TOF optical sensing module 300 is disposed below a protection cover plate 400 and includes a cap 310, a light-emitting unit 320, a sensor chip 330 and a substrate 350. The substrate 350, such as a printed circuit board, includes one or multiple insulating layers and electroconductive layers (not shown). The light-emitting unit 320 and the sensor chip 330 are disposed above the substrate 350 through an adhesive material. The light-emitting unit 320 and the sensor chip 330 are electrically connected to the substrate 350. At least a first pixel (or reference pixel) 331 and at least a second pixel (or sensing pixel) 341 are formed on the sensor chip 330. The optical sensing module 300 further includes a control processing circuit, such as an integrated circuit, for controlling the light-emitting unit 320 to emit light, controls the first pixel 331 to receive light, controls the second pixel 341 to receive light and processes the electrical signals generated after the first pixel 331 and the second pixel 341 have received light. The cap 310 has a transmitting window 314 and a receiving window 312 and is disposed above the substrate 350 to accommodate the light-emitting unit 320 and the sensor chip 330 on the substrate 350 within a chamber 315 of the cap 310. The light-emitting unit 320 outputs detection light L1 to the object (not shown) through the transmitting window 314 and the protection cover plate 400. The second pixel 341 receives sensing light L3 reflected from the object through the protection cover plate 400 and the receiving window 312. The detection light L1 is reflected by the cap 310 to generate reference light L2 travelling toward the first pixel 331. On the other hand, a portion of the detection light L1 travelling out of the chamber 315 through the transmitting window 314 is reflected between the protection cover plate 400 and the cap 310, then enters the chamber 315 through the receiving window 312, and is then received by the second pixel 341, thereby interfering the sensing result of the second pixel 341. For example, the stray light L4 interferes with the sensing result. Thus, how to reduce the stray light interference is an issue to be solved by this disclosure.

### BRIEF SUMMARY OF THE INVENTION

It is therefore an objective of this disclosure to provide a TOF optical sensing module with a stray-light guide-away structure properly designed to effectively reduce the interference.

To achieve the above-identified objective, this disclosure provides a TOF optical sensing module to be disposed below a protection cover plate. The TOF optical sensing module includes: a substrate; a cap having a cap body, and a receiving window, a transmitting window and a stray-light guide-away structure, which are connected to the cap body, wherein the cap and the substrate commonly define a chamber body; and a transceiving unit, which is disposed on the substrate, in the chamber body, outputs detection light through the transmitting window, and receives sensing light through the receiving window. The stray-light guide-away structure is disposed between an outer side between the protection cover plate and the cap body and between the transmitting window and the receiving window, and stops stray light from entering the transceiving unit through the receiving window.

With the above-mentioned TOF optical sensing module, the influence of the stray light between the optical sensing module and the protection cover plate on the sensing result can be effectively reduced, and the interference can be reduced.

In order to make the above-mentioned summary of this invention become more obvious and understandable, a detailed description of the preferred embodiments will be provided in the following in conjunction with the accompanying drawings.

### BRIEF DESCRIPTION OF THE SEVERAL VIEWS OF THE DRAWINGS

FIG. 1 is a schematic view showing a conventional TOF optical sensing module.

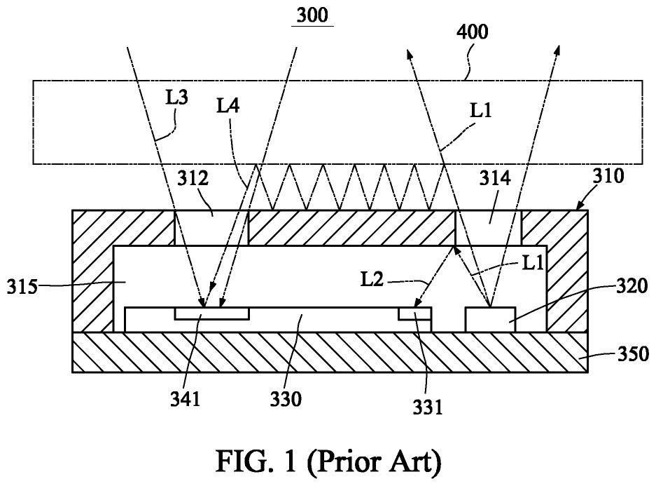

FIG. 2 is a schematic view showing a TOF optical sensing module according to a preferred embodiment of this disclosure.

FIG. 3 is a schematic view showing a modified example of the TOF optical sensing module of FIG. 2.

FIG. 4 is a schematic view showing a modified example of a combination of a stray-light guide-away structure and a cap.

### DETAILED DESCRIPTION OF THE INVENTION

This disclosure preferably adopts a package process, which may also be a wafer-scale package process, to form a stray-light guide-away structure on an outer side of a cap body of a package cap, and thus to minimize the interference of the stray light travelling between the cap and the protection cover plate, thereby increasing the signal-to-noise ratio (SNR) of a sensing pixel and solving the conventional problems. In a specific embodiment, the stray-light guide-away structure on the outer side of the cap body of the cap has an angled reflection structure to reflect the stray light, travelling between the outer side of the cap body of the cap and the protection cover plate, away from the sensing pixel, to prevent the stray light from entering the sensing pixel and thus to reduce the interference.

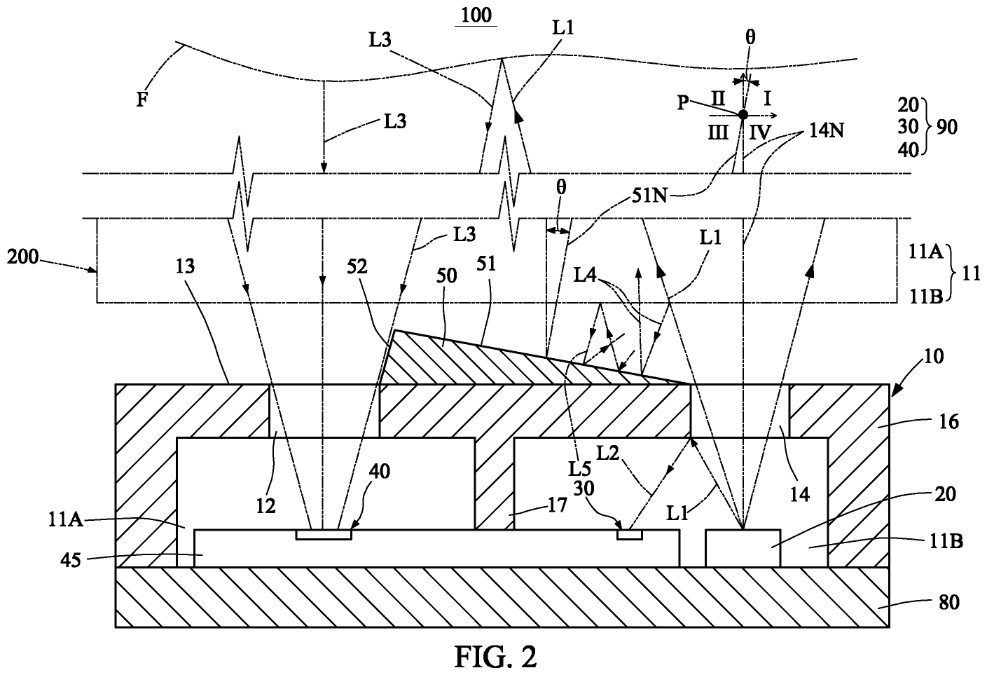

FIG. 2 is a schematic view showing a TOF optical sensing module 100 according to a preferred embodiment of this disclosure. Referring to FIG. 2, the TOF optical sensing module 100 to be disposed below a protection cover plate 200 includes a cap 10, a substrate 80 and a transceiving unit 90. The cap 10 has a cap body 16, and a receiving window 12, a transmitting window 14 and a stray-light guide-away structure 50, all of which are connected to the cap body 16. The cap 10 and the substrate 80 commonly define a chamber body 11 therebetween. The cap body 16 has an inner side defining the chamber body 11 and an outer side 13 disposed outside the chamber body 11. The transceiving unit 90 disposed on the substrate 80 and in the chamber body 11 outputs detection light L1 through the transmitting window 14, and receives sensing light L3 through the receiving window 12. The stray-light guide-away structure 50 is disposed between the protection cover plate 200 and the outer side 13 of the cap body 16 and between the transmitting window 14 and the receiving window 12, and guides stray light L4 and/or L5 away from the receiving window 12 to stop the stray light L4 and/or L5 from entering the transceiving unit 90 through the receiving window 12 and thus from interfering the sensing result, wherein the stray light L4 comes from a light-emitting unit 20 within the chamber body 11, and the stray light L5 comes from an external environment. It can be understood that although the stray light L5 of FIG. 2 still travels in a direction toward a location close to the receiving window 12 upon being reflected by a first surface 51 of the stray-light guide-away structure 50, the stray light L5 finally travels in a direction away from the receiving window 12 after being subsequently reflected by the first surface 51 because the first surface 51 has a tilt angle. It is understandable that the stray light L4 also has the reflecting condition similar to that of the stray light L5.

In this embodiment, each of the receiving window 12 and the transmitting window 14 is a light-transmission region through which the to-be-measured light is transmitted. The receiving window 12 and the transmitting window 14 penetrate through the cap body 16 having the opaque inverse-U shaped structure. In another embodiment, the cap body 16 of the cap 10 may further have a separation structure 17 disposed below the stray-light guide-away structure 50 and contacting a sensing chip 45 to separate the chamber body 11 into two optically isolated sub-chamber bodies 11A and 11B to prevent stray light interference of different chamber bodies. In one example, the chamber body 11 is a solid body made of a light-transmission molding compound, and the cap body 16 is made of an opaque material, such as an opaque molding compound, metal and the like, and covers the chamber body 11 of the light-transmission molding compound with a portion of the light-transmission molding compound corresponding to each of the receiving window 12 and the transmitting window 14 being exposed. In another example, the chamber body 11 may be filled with air with the pressure higher than or lower than one atmosphere. It can be understood that the cap 10 of this embodiment can be previously formed and adhered to the substrate 80. For example, the cap 10 can be directly and partially or entirely formed on the substrate 80 by way of injection molding. The receiving window 12 and the transmitting window 14 may be hollow openings, may be optical devices having special optical functions, such as optical filters of specific wavelengths, lenses or diffractive elements with the light defocusing or focusing function, and the like, or may be combinations of elements with multiple optical functions, such as the former two elements.

In this embodiment, the transceiving unit 90 includes the light-emitting unit 20, a light reference region 30 and a light sensing region 40. The protection cover plate 200 is a glass cover plate, and may also be a display, a touch panel and the like, or a combination thereof. The light reference region 30 and the light sensing region 40 are disposed at different positions of the sensing chip 45 (or the light reference region 30 and the light sensing region 40 may be disposed on different chips), wherein the light reference region 30 is closer to the light-emitting unit 20, while the light sensing region 40 is farther away from the light-emitting unit 20.

The material of the sensing chip 45 may include a semiconductor material, such as silicon, germanium, gallium nitride, silicon carbide, gallium arsenide, gallium phosphide, indium phosphide, indium arsenide, indium antimonide, silicon germanium alloy, gallium arsenide phosphide alloy, aluminum indium arsenic alloy, aluminum gallium arsenic alloy, gallium indium arsenic alloy, gallium indium phosphide alloy, gallium indium arsenic phosphide alloy or a combination of the above-mentioned materials. The sensing chip 45 may further include one or multiple electrical components (e.g., integrated circuits). The integrated circuit may be an analog circuit or a digital circuit, which may be implemented and formed in the chip to achieve the electrical connections according to the electrical design and the function of the chip, and may include an active device, a passive device, an electroconductive layer, a dielectric layer and the like. The sensing chip 45 may be electrically connected to the substrate 80 of the TOF optical sensing module 100 through bonding wires or electroconductive bumps, and thus electrically connected to the external device and the light-emitting unit 20 to control the operations of the light-emitting unit 20, the light reference region 30 and the light sensing region 40 and to provide a signal processing function.

The light reference region 30 and the light sensing region 40 respectively include one or multiple reference pixels and one or multiple sensing pixels, wherein the pixels are arranged in a one-dimensional array or a two-dimensional array. The reference (sensing) pixel receives the reference (sensing) light. A portion of the reference (sensing) pixel has a photosensitive structure, such as a photodiode, an avalanche photodiode (APD) and the like, which is the SPAD in this embodiment. The other portion of the reference (sensing) pixel has a sensing circuit for processing the electrical signal coming from the photosensitive structure. The sensing chip 45 may be manufactured using, for example, a complementary metal-oxide semiconductor (CMOS) manufacturing process, such as a front side illumination (FSI), a back side illumination (BSI) manufacturing process, or any other semiconductor manufacturing process. However, this disclosure is not restricted thereto. The substrate 80 includes one or multiple insulating layers and one or multiple electroconductive layers, and may be one of a printed circuit board, a ceramic substrate and the like.

The light-emitting unit 20 is disposed on the substrate 80, is correspondingly disposed below the transmitting window 14, and outputs the detection light L1. The detection light L1 travels by a distance through the transmitting window 14 and then irradiates a target F. Then, the target F reflects the detection light L1 and outputs the sensing light L3, wherein the target F may be an organism target or a non-organism target. A portion of the sensing light L3 is received by the light sensing region 40 of the sensing chip 45 through the receiving window 12, and converted into the electrical signal. The light sensing region 40 is disposed below the receiving window 12, and receives the sensing light L3 through the receiving window 12 to generate an electric sensing signal. However, the distance to the target F needs to be calculated according to the time instant when the light sensing region 40 receives the signal with reference to a reference time instant. According to the TOF formula, 2L=CΔt is obtained, where L denotes the distance from the optical sensing module 100 to the target F, C denotes the speed of light, and Δt denotes the travelling time of light (herein defined as the time difference between the emitting time and the receiving time). Therefore, in addition to obtaining the time instant when the light sensing region 40 receives the sensing light L3, the start time instant when the light reference region 30 emits the detection light L1 also needs to be obtained.

The light reference region 30 disposed below the cap 10 receives the reference light L2 to generate an electrical reference signal. In this embodiment, the light reference region 30 is disposed below an opaque region of the cap body 16 of the cap 10, which is disposed between the receiving window 12 and the transmitting window 14. The information of the distance from the target F to the TOF optical sensing module 100 can be obtained according to the difference between the time of receiving the electrical reference signal and the time of receiving the electric sensing signal.

In one example, the light-emitting unit 20 is configured to emit the radiation (e.g., infrared (IR) light) with a specific frequency or frequency range. In several examples, the light-emitting unit 20 is the VCSEL or a light-emitting diode (LED), such as an infrared LED. The light-emitting unit 20 may be attached to the upper surface of the substrate 80 through an adhesive material, and can be electrically connected to the substrate 80 through bonding wires or electroconductive bumps, for example.

In addition, a portion of the detection light L1 outputted from the light-emitting unit 20 is reflected by the protection cover plate 200, and the stray light L4 is thus generated. In order to prevent the stray light L4 from being sensed by the light sensing region 40 and thus from affecting the actual sensing result of the sensing light L3, this embodiment is implemented by disposing the stray-light guide-away structure 50 between the protection cover plate 200 and the outer side 13 and between the transmitting window 14 and the receiving window 12. The angle of the stray-light guide-away structure 50 can be designed to guide the stray light L4 away from the receiving window 12 and to stop the stray light L4 from entering the light sensing region 40 through the receiving window 12 in a manner including, without limitation to: (a) reflecting the stray light L4 in a direction away from the receiving window 12; and (b) reflecting the stray light L4 in a direction of transmitting through the protection cover plate 200.

In this example, although the depicted sensing light L3 is symmetrical about an incident normal (perpendicular to the sensing pixel of the light sensing region 40) and has the left boundary and right boundary at the same angle with respect to the incident normal, this disclosure is not restricted thereto. In another example, the sensing light may be asymmetrical about the incident normal and has the left boundary and right boundary at different angles with respect to the incident normal. In still another example, the angular range of the sensing light is disposed on only the left side or the right side of the incident normal.

In this embodiment, the stray-light guide-away structure 50 is a wedge structure, which is tapered from the receiving window 12 to the transmitting window 14. In the cross-sectional view of FIG. 2, the stray-light guide-away structure 50 has a triangular shape. However, the actual stray-light guide-away structure 50 may be similar to a three-dimensional hillside structure. It can be understood that the first surface 51 of the stray-light guide-away structure 50 reflects the stray light L4 away from the receiving window 12. The first surface 51 is an inclined surface, but this disclosure is not restricted thereto because the first surface 51 may also be a curved surface, a serrate surface and the like inclined from the receiving window 12 to the transmitting window 14. Geometrically, a normal 51N of the first surface 51 intersects with a normal 14N of the transmitting window 14 to form acute angles θ in the first quadrant I and third quadrant III, where 0<8<90 degrees, wherein the normal is defined with respect with one surface. The normal 51N intersects with the normal 14N at a point P in FIG. 2, and the first quadrant I, second quadrant II, third quadrant III and fourth quadrants IV are defined about the point P serving as the original. The first surface 51 may be made of a high light-absorbing material or have a roughened surface to increase the light-absorbing property to reduce the reflecting ability. It can be understood that the inclined surface may be a macroscopically inclined surface but a microscopically rough structure, and can reflect a portion of stray light and absorb another portion of stray light. In addition, the stray-light guide-away structure 50 may further include a second surface 52, which is an inclined surface connected to the first surface 51, and defines a portion of a field of view (FOV) of the light sensing region 40. Thus, the FOV of the light sensing region 40 may further be defined by the stray-light guide-away structure 50 in conjunction with the receiving window 12. That is, the maximum angle of the right-side boundary of the sensing light L3 in FIG. 2 can be restricted by the second surface 52.

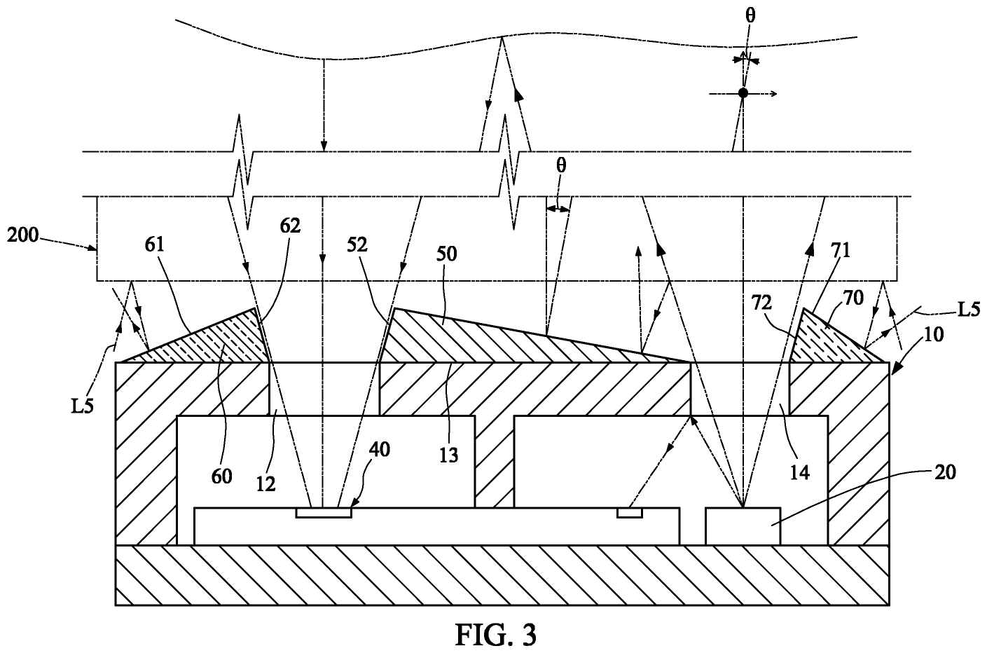

FIG. 3 is a schematic view showing a modified example of the TOF optical sensing module of FIG. 2. As shown in FIG. 3, the acute angle θ similar to FIG. 2 may also be defined, and the cap 10 further includes a second stray-light guide-away structure 60 disposed between the protection cover plate 200 and the outer side 13 of the cap body 16, so that the receiving window 12 is disposed between the second stray-light guide-away structure 60 and the stray-light guide-away structure 50. The second stray-light guide-away structure 60 has a first surface 61 for guiding the stray light L5 away from the receiving window 12; and a second surface 62 for completely defining the FOV of the light sensing region 40 together with the second surface 52 of the stray-light guide-away structure 50.

In addition, the cap 10 may further include a third stray-light guide-away structure 70 disposed between the protection cover plate 200 and the outer side 13 of the cap body 16, so that the transmitting window 14 is disposed between the third stray-light guide-away structure 70 and the stray-light guide-away structure 50. The third stray-light guide-away structure 70 has a first surface 71 for guiding the stray light L5 away from the transmitting window 14 and the receiving window 12; and a second surface 72 for defining a portion of the range of emitting angle of the light-emitting unit 20.

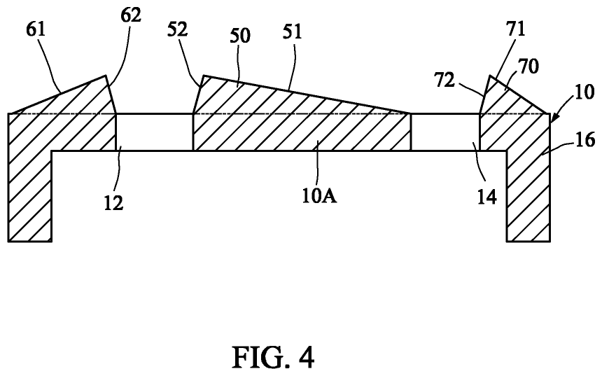

FIG. 4 is a schematic view showing a modified example of a combination of a stray-light guide-away structure and a cap. Referring to FIG. 4, the opaque cap body 16 of the cap 10 and the stray-light guide-away structure 50 form a one-piece structure formed by the same material. Thus, after a package mold has been designed and manufactured, a package material can be used to form an integral structure conveniently using the package mold.

It is worth noting that all the above embodiments can be combined, replaced or modified interactively as appropriate to provide various combination effects. The TOF optical sensing module can be applied to various electronic apparatuses, such as a mobile phone, a tablet computer, a camera and/or a wearable computer device capable of being attached to clothes, a shoe, a watch, glasses or any other arbitrary wearable structure. In some embodiments, the TOF optical sensing module or the electronic apparatus itself may be installed in traffic tools, such as a steamship and a vehicle, a robot or any other movable structure or machine.

With the above-mentioned TOF optical sensing module, the influence of the stray light, which is induced by the detection light in the chamber body and continuously reflected between the optical sensing module and the protection cover plate on the sensing result can be effectively reduced, so that the interference can be effectively reduced.

While this disclosure has been described by way of examples and in terms of preferred embodiments, it is to be understood that this disclosure is not limited thereto. To the contrary, it is intended to cover various modifications. Therefore, the scope of the appended claims should be accorded the broadest interpretation so as to encompass all such modifications.

1. A time of flight (TOF) optical sensing module to be disposed below a protection cover plate, the TOF optical sensing module comprising:
a substrate;
a cap having a cap body, and a receiving window, a transmitting window and a stray-light guide-away structure, which are connected to the cap body, wherein the cap and the substrate commonly define a chamber body; and
a transceiving unit, which is disposed on the substrate and in the chamber body, outputs detection light through the transmitting window, and receives sensing light through the receiving window, wherein the stray-light guide-away structure is disposed between the protection cover plate and an outer side of the cap body and between the transmitting window and the receiving window, and stops stray light from entering the transceiving unit through the receiving window.

2. The TOF optical sensing module according to claim 1, wherein the transceiving unit comprises:
a light-emitting unit being disposed below the transmitting window and outputting the detection light irradiating a target through the transmitting window, so that the target outputs the sensing light, wherein the detection light is reflected by the protection cover plate to generate the stray light; and
a light sensing region, which is disposed below the receiving window and receives the sensing light through the receiving window to generate an electric sensing signal, wherein the stray-light guide-away structure stops the stray light from entering the light sensing region through the receiving window.

3. The TOF optical sensing module according to claim 2, wherein the detection light is reflected within the cap to generate reference light, and the transceiving unit further comprises:
a light reference region, which is disposed below the cap and receives the reference light to generate an electrical reference signal.

4. The TOF optical sensing module according to claim 1, wherein the stray-light guide-away structure comprises: a first surface reflecting the stray light away from the receiving window.

5. The TOF optical sensing module according to claim 4, wherein the first surface is an inclined surface inclined downwards from the receiving window to the transmitting window.

6. The TOF optical sensing module according to claim 4, wherein a normal of the first surface intersects with a normal of the transmitting window to form acute angles θ in a first quadrant and a third quadrant, where 0<0<90 degrees.

7. The TOF optical sensing module according to claim 4, wherein the stray-light guide-away structure further comprises: a second surface connected to the first surface, wherein the second surface defines a portion of a field of view of a light sensing region of the transceiving unit.

8. The TOF optical sensing module according to claim 7, wherein the second surface is an inclined surface.

9. The TOF optical sensing module according to claim 5, wherein the stray-light guide-away structure further comprises: a second surface connected to the first surface, wherein the second surface defines a portion of a field of view of a light sensing region of the transceiving unit.

10. The TOF optical sensing module according to claim 9, wherein the second surface is an inclined surface.

11. The TOF optical sensing module according to claim 6, wherein the stray-light guide-away structure further comprises: a second surface connected to the first surface, wherein the second surface defines a portion of a field of view of a light sensing region of the transceiving unit.

12. The TOF optical sensing module according to claim 11, wherein the second surface is an inclined surface.

13. The TOF optical sensing module according to claim 1, wherein the stray-light guide-away structure is a wedge structure tapered from the receiving window to the transmitting window.

14. The TOF optical sensing module according to claim 1, wherein the cap further comprises a second stray-light guide-away structure disposed on the outer side and between the protection cover plate and the outer side, so that the receiving window is disposed between the second stray-light guide-away structure and the stray-light guide-away structure, wherein the second stray-light guide-away structure guides the stray light away from the receiving window.

15. The TOF optical sensing module according to claim 14, wherein the cap further comprises a third stray-light guide-away structure disposed on the outer side and between the protection cover plate and the outer side, so that the transmitting window is disposed between the third stray-light guide-away structure and the stray-light guide-away structure, wherein the third stray-light guide-away structure guides the stray light away from the transmitting window and the receiving window.

16. The TOF optical sensing module according to claim 1, wherein the cap further comprises a third stray-light guide-away structure disposed on the outer side and between the protection cover plate and the outer side, so that the transmitting window is disposed between the third stray-light guide-away structure and the stray-light guide-away structure, wherein the third stray-light guide-away structure guides the stray light away from the transmitting window and the receiving window.

17. The TOF optical sensing module according to claim 1, wherein the cap body and the stray-light guide-away structure form a one-piece structure formed by of a same material.

18. The TOF optical sensing module according to claim 1, wherein the cap body further has a separation structure separating the chamber body into two sub-chamber bodies and optically isolates the two sub-chamber bodies from each other.

19. The TOF optical sensing module according to claim 18, wherein the separation structure is disposed under the stray-light guide-away structure.
